(19) United States
(12) Patent Application Publication
(10) Pub. No.: US 2024/0178793 A1
(43) Pub. Date: May 30, 2024

(54) METHOD AND APPARATUS FOR REDUCING SOLAR CELL DEGRADATION

(71) Applicant: National Research Council of Canada, Ottawa (CA)

(72) Inventors: Salima ALEM, Ottawa (CA); Ye TAO, Ottawa (CA); Jianping LU, Orleans (CA); Badrou Reda AICH, Saint-Henri de Levis (CA); Neil GRADDAGE, Ottawa (CA); Zhiyi (Frank) ZHANG, Ottawa (CA)

(73) Assignee: National Research Council of Canada, Ottawa (CA)

(21) Appl. No.: 17/993,936

(22) Filed: Nov. 24, 2022

(51) Int. Cl. H02S 99/00; H02S 50/10

(52) U.S. Cl. CPC H02S 99/00; H02S 50/10; H10K 30/50

(57) ABSTRACT

Methods and systems for reducing solar cell degradation are provided. The methods and systems related to frequently applying large reverse bias current-voltage (J-V) sweeps to the cell to reduce the rates of internal degradation of the solar cells. The frequent sweeps serve to detrap charge carriers formed in the cell due to photo-oxidative damage. This detrapping reduces the rate of power conversion efficiency (PCE) degradation throughout the life of the solar cell.

### FIELD

The present disclosure relates generally to methods and apparatus for improving the lifespan and efficiency of solar cells.

### INTRODUCTION

The following paragraphs are not an admission that anything discussed in them is prior art or part of the knowledge of persons skilled in the art.

Photovoltaic solar cells have received a great deal of attention in industrial and research contexts over the past several decades. A large shift in this focus is due to the desire to shift power generation away from carbon intensive energy sources to address climate change. This increased focus has led to research in developing more efficient, economical, and resilient solar cells for use in more contexts.

The last decade in particular has seen a significant increase in the efficiency of polymer bulk heterojunction (BHJ) solar cells thanks to developments which result in increasing optical absorption, reduced voltage loss, better control of the blend morphology and more efficient interfaces. The highest reported power conversion efficiency (PCE) for a lab-scale device fabricated by spin coating is greater than 17%. However, although this PCE enables devices with comparable performance to a-Si cells, such cells typically display rapid PCE degradation preventing commercial adoption as both efficiency and lifetime are crucial factors for commercial viability of solar cells.

There is a great deal of research devoted to understanding the degradation mechanisms in solar cells. Those mechanisms can broadly be grouped into two categories: extrinsic degradation caused by chemical reactions with water and oxygen, and intrinsic degradation induced by molecular rearrangement within the active layer or interlayers of the solar cell.

Extrinsic degradation can be controlled through proper encapsulation of the solar cells to slow down the permeation of oxygen and moisture into the device. However, remedies for intrinsic degradation are more ambiguous, with research looking at selecting inherently stable materials and locking of the active layer morphology.

The typical decay profile of a polymer solar cell under light exposure consists of a fast decrease in performance during initial operation, commonly referred to as the “burn-in loss”, followed by a linear decay where the slop defines the lifetime of the device. The photo-induced burn-in loss is the predominant loss mechanism over the lifetime of polymer BHJ solar cells. In devices using blends of poly[N-9″-hepta-decanyl-2,7carbazole-alt-5,5-(4′,7′-di-2-thienyl-2′,1′,3′-benzothiadiazole)] (PCDTBT) and [6,6]-phenyl C71 butyric acid methyl ester (PC₇₀BM), hereinafter PCDTBT:PC₇₀BM, (one of the most studied systems), the burn-in loss is correlated with the creation of sub-bandgap states due to photo-induced reaction which increases the energetic disorder in the active layer. Effective solutions have been demonstrated to reduce the burn-in losses in PCDTBT-based solar cells. These include using a purified high-molecular weight PCDTBT with dense and ordered film morphologies. However, these solutions require the use of expensive compositions.

As such, there is still a need in the field to find other methods and devices for addressing and seeking to reduce PCE degradation in such solar cells.

### SUMMARY OF THE INVENTION

In one embodiment a method is set forth for reducing solar cell degradation. The method comprises the steps of intermittently applying a reverse bias voltage during a current-voltage (J-V) sweep or scan of the cell.

In another embodiment a system is set forth for reducing solar cell degradation. The system comprises a means for generating a reverse bias J-V sweep and is configured to intermittently apply the sweep to the solar cell.

### BRIEF DESCRIPTION OF THE DRAWINGS

The drawings included herewith are for illustrating various examples of apparatuses, methods, and data of the present disclosure and are not intended to limit the scope of what is taught in any way.

FIG. 1A, FIG. 1B, FIG. 1C, FIG. 1D, FIG. 1E and FIG. 1F show the evolution of the photovoltaic parameters of aged PCDTBT:PC₇₀BM inverted solar cells under intermittent irradiation (7 hours/day) at different bias sweeps and frequency.

FIG. 2 shows a comparison of EQE spectra and total absorption spectra of two PCDTBT:PC70BM inverted solar cells with aged active layers in the dark and under 100 mW/cm2 solar simulator light respectively.

FIG. 3A shows Cole-Cole plots of a fresh device and devices aged under different conditions with the inset showing the equivalent circuit used in fitting the impedance curve.

FIG. 3B shows a Cole-Cole plot of a device with an aged active layer with the inset showing the equivalent circuit used in fitting the impedance curve.

FIG. 4A and FIG. 4B show the (A) frequency dependent real parts and (B) frequency-dependent imaginary parts in the impedance spectra of a fresh PCDTBT:PC70 BM device aged under AM 1.5 G irradiation with different J-V characterization conditions.

### DETAILED DESCRIPTION

Various apparatuses or methods will be described below to provide an example of an embodiment of each claimed invention. No embodiment described below limits any claimed invention and any claimed invention may cover apparatuses and methods that differ from those described below. The claimed inventions are not limited to apparatuses and methods having all of the features of any one apparatus or method described below, or to features common to multiple or all of the apparatuses or methods described below. It is possible that an apparatus or method described below is not an embodiment of any claimed invention. Any invention disclosed in an apparatus or method described below that is not claimed in this document may be the subject matter of another protective instrument, for example, a continuing patent application, and the applicant(s), inventor(s) and/or owner(s) do not intend to abandon, disclaim or dedicate to the public any such invention by its disclosure in this document.

Although it is widely understood that the degradation rate depends on the material system and the device structure, it is difficult to make a clear comparison between the lifetime of devices since testing and environmental conditions vary between laboratories. To remedy this, standard procedures for accurate lifetime determination have been established, including four different categories of test protocols: shelf life, outdoor, indoor and thermal cycling. These were defined at the international summits on organic photovoltaic (OPV) stability (ISOS 2008-2010). The findings of these summits were incorporated into multiple international standards, including IEC TS 62876-2-1, which defines protocols for stability testing of nano-enabled photovoltaic devices. This technical specification outlines the parameters that should be reported when measuring device lifetime, but does not specify the range and frequency of current-voltage (J-V) scans outside of the burn-in period. IEC 60904-1 provides a standard for measurement of J-V characteristic, but again it does not specify limits on voltage range, only that sweeps should include the J_{SC} and V_{OC}.

The inventors have discovered that applying large reverse bias voltage during frequent J-V sweeps has a significant effect on slowing the degradation rate of photovoltaic cells. Without wishing to be bound to theory, the Inventors believe that the decay in photovoltaic performance is related to an increase in the series resistance and a decrease in the shunt resistance of the devices over time. Further characterization of bulk heterojunction layers under irradiation conditions suggests that this behavior may be caused by the decreasing mobility of charge carrier due to the formation of defects or traps in the layer, induced by photo-oxidation processes. In addition, charge carrier extraction time was found to increase from 7 μs to more than 400 μs after photodegradation. The frequent application of a large reverse bias sweep is believed by the inventors to de-trap the charge carriers and thereby slow the device degradation. Impedance analysis has indicated that during the decay of PCDTBT:PC₇₀BM devices the bulk layer becomes more resistive over time, and applying large and frequent reverse bias sweeps during this period can significantly slow down this process.

The inventors have chosen to research this method using PCDTBT based polymer inverted solar cells due to their excellent stability in air, good printing properties, high PCE under indoor light, and demonstrated uses in sensing and photo-detection. The below described experiments were performed using inverted PCDTBT:PC₇₀BM solar cells without any encapsulation under simulated real world exposure to light (ISOS-L-1). These experiments detailed the effects of bias range and frequency of testing on the photovoltaic parameters by characterizing the devices repeatedly using J-V scans. Following these experiments, further experiments were performed to investigate the degradation characteristics of the PCDTBT:PC₇₀BM layer using impedance spectroscopy. Finally the charge extraction dynamics were investigated through equivalent circuit analysis to determine the relationship between the resistance and capacitance values as a function of bias sweep voltage and frequency.

While the inventors have focused their investigations on PCDTBT based cells, specifically PCDTBT:PC₇₀BM solar cells, due to the reasons above, it is believed that similar devices and methods would be of use for reducing PCE degradation for polymer BHJ cells generally, with possible further applications in solar cells more generally. Specifically, the method and systems described herein are believed to be applicable for use with any photovoltaic solar cells where photo-induced defects are created which cause photogenerated charge traps to form within the cell over time.

### Experimental Procedures

### Materials

PCDTBT (Mn=27 kDa, Mw=55 kDa) and PC₇₀BM were purchased from Brilliant Matters Inc. and Nano-C respectively, and used without any further purification. For the electron extraction interlayer, a ZnO nanoparticle solution was prepared. Molybdenum oxide (MoOₓ) purchased from Sigma-Aldrich was used for the hole extraction layer, without further purification.

### Device Fabrication and Characterization

The BHJ inverted solar cells structure is PET/ITO/ZnO/PCDTBT:PCOBM/MoOₓ/Ag. Devices were fabricated on indium tin oxide (ITO) coated PET substrates, purchased from Sigma Aldrich. Each 10 cm×10 cm substrate contained 10 single cells, each with an active area of 1 cm². The sheet resistance and thickness of the ITO are 60 Ω/sq and 130 nm, respectively. The ITO sheets were patterned using a screen printable etching paste (SolarEtch® AXS Type 20), and an EKRA X1-SL flatbed screen printer with a 350 mesh stainless steel screen. After curing the paste for 10 min at 120° C., the etched ITO was stripped off with deionized water. The ITO sheets were thoroughly cleaned afterwards in detergent and DI water, then ultrasonicated in acetone and isopropyl alcohol for 5 min before being dried in an oven at 100° C. for 10 min.

The ZnO nanoparticle film was blade-coated onto the patterned ITO substrate at a speed of 2.5 mm/s and a gap of 300 μm, before being dried at 100° C. for 10 min on a hotplate.

A PCDTBT:PC₇₀BM ink was prepared in 1,2-dichlorobenzene, with a weight ratio of 1:3 and PCDTBT concentration of 7 mg/ml. The ink was prepared three days before coating and heated on a stirring hotplate at 100° C. overnight prior to deposition. The active layer was blade-coated at a speed of 5 mm/s with a gap of 500 μm.

Finally, to complete the solar cell architecture a bilayer cathode consisting of 100 nm of Ag on top of 10 nm of MoOₓ was thermally evaporated through a shadow mask onto the active layer to form cells with an active area of 1 cm².

The thickness of films was measured by a Dektak profilometer and a ZYGO NewView 7300 optical profiler. The J-V characteristics were recorded using a Keithley 2400 Digital Source Meter together with a Keithley series 3700A Multiplexer, through a LabVIEW interface that facilitates control of up to 10 devices. The photocurrent was generated under air mass 1.5 global (AM 1.5G) irradiation of 100 mW/cm² from a Newport Sol3A Class AAA solar simulator (model: 94123A) with a 1600 W xenon arc lamp. The light intensity was adjusted using a calibrated Si photodiode with a quartz window purchased from Newport (91150V). The external quantum efficiency (EQE) was measured using a Jobin-Yvon Triax spectrometer, a Jobin-Yvon xenon light source, a Merlin lock-in amplifier, a calibrated Si UV detector, and an SR570 low noise current amplifier. It is worth pointing out that the short-circuit photocurrent reported in this paper was always calculated from the wavelength integration of the product of the EQE curve and the standard AM 1.5G solar spectrum. All devices were tested in a sealed acrylic box with a quartz window, which was filled with dry air in order to avoid the fluctuation of the ambient humidity and ensure consistent environmental conditions.

The organic field effect transistor (OFET) devices were fabricated on n-doped Si/SiO₂ substrates containing prefabricated interdigitated gold source-drain electrodes with a channel length of 20 μm and a channel width of 1 cm. PCDTBT:PC₇₀BM solutions, the same as the ones used in OPV devices, were spin cast on top. The hole mobility was deduced from the saturation regime of the current-voltage characteristics.

For impedance spectroscopy measurements, an LCR meter (Agilent 4284A) was used to measure the impedance of the devices in the frequency range from 20 Hz to 1 MHz. Typically an AC voltage amplitude of 30 mV was used to probe the solar cells. A four-probe configuration was used in order to reduce cable effects. EIS Spectrum Analyzer software was used to fit impedance data and generate the equivalent circuits. All impedance measurements were conducted in the dark to prevent additional capacitive effects in the devices due to photo-generated charge carriers.

While the above materials are those used by the inventors to create the devices used for testing purposes those skilled in the art would be aware of other materials or processes which can be used for the fabrication of the device in question. Some preferred materials for forming the solar cells include: organic semiconductors (e.g. polymers, small molecules, oligomers), perovskite, quantum dots, metal chalcogenides, and metal oxides. The methods and systems described herein could also be used with solar systems using a combination of cells formed from different appropriate materials.

### Investigation and Testing

To investigate the effect of impact of large reverse bias voltage sweeps, a batch of more than forty blade-coated PCDTBT:PC70BM-based solar cells were prepared with an average initial PCE of (4.4±0.2) %. All devices were exposed for 7 hours a day to AM 1.5 G simulated solar light, mimicking outdoor conditions. Devices were characterized by performing J-V scans at regular intervals during light exposure, and they were kept at open circuit condition between scans. The performance of the devices was monitored for 100 hours under simulated solar irradiation, approximately 13 days in total.

The J-V scans were performed using a Keithley 2400 SourceMeter to generate the reverse bias scan. During the scan the cells were disconnected from the load to which they output power. In general the J-V scans would last no more than 15 seconds to scan the entire range following which the cells were then reconnected to their normal output load. While such systems were used by the inventors to perform the J-V scans a skilled person would understand that other any controllable voltage source could be used to apply a reverse bias across the devices. A practical implementation of this could be integrated into a solar panel control circuit, wherein the control circuit would disconnect the normal output load, apply the reverse bias to the panels at appropriate intervals to maximise device lifetime and duty cycle and then reconnect the cells to the output load once the scan is completed.

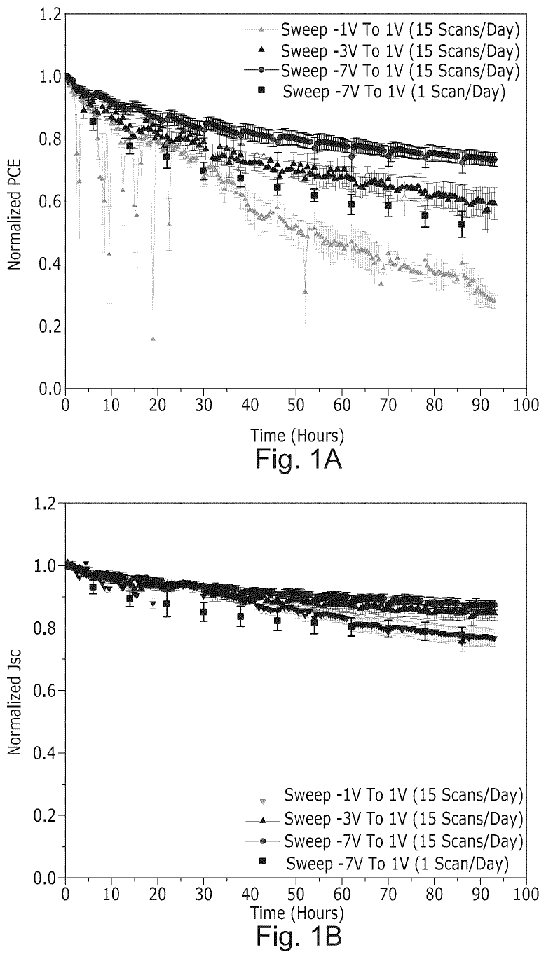

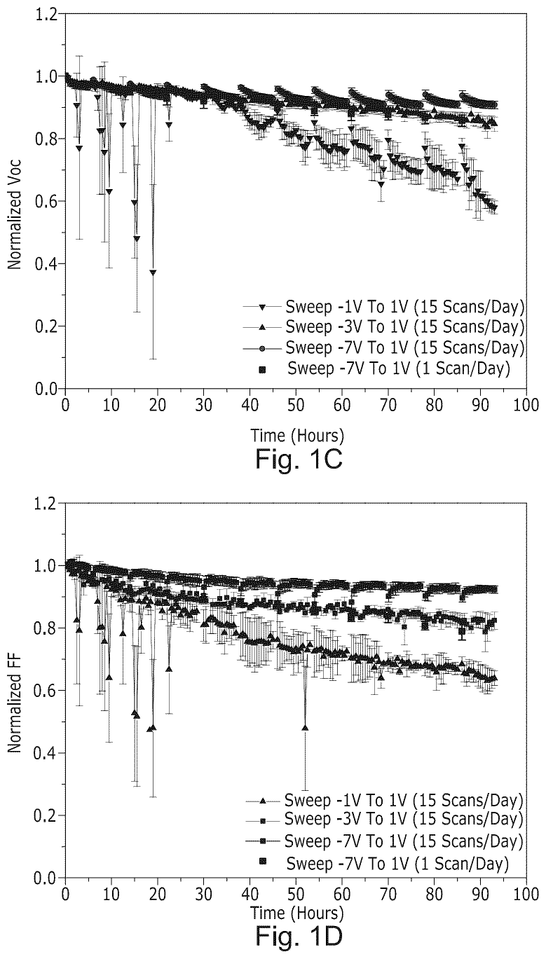

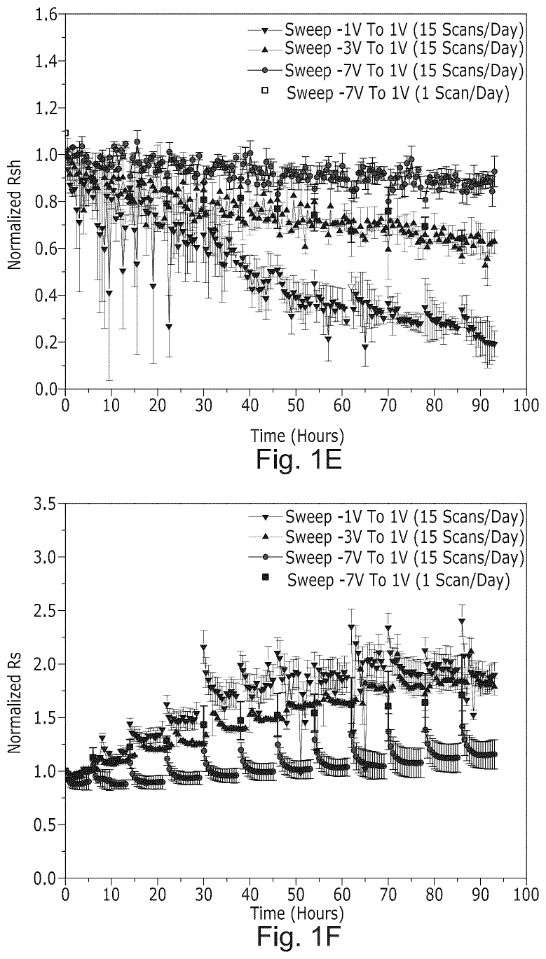

FIG. 1A, FIG. 1B FIG. 1C, FIG. 1D, FIG. 1E and FIG. 1F show the evolution of the photovoltaic parameters when characterized using different ranges of voltage sweep (−7 V to +1 V, −3 V to +1 V and −1 V to +1 V) and at different frequencies of J-V scans performed per day (15 times vs. 1 time). All parameters are normalized to their initial value for a clear comparison. The PCE decay integrates the changes in J_{SC}, V_{OC} and FF since it is derived from their product. The devices swept from −1 V underwent a fast degradation with a decrease of more than 70% in the PCE at the end of the testing period, whereas in the devices swept from −3 V and −7 V the PCEs decreased approximately 40% and 24% from their initial value respectively. The decay became even slower (˜20%) when the devices were scanned from −10 V to 1 V. However, this data is not included because most of the devices did not sustain such a high reverse bias, with breakdown of the active layer causing short-circuits. While the −10 V to 1 V scan resulted in short-circuits in the devices that were used by the inventors, the inventors believe that using higher voltage reverse bias scans will result in further reductions in PCE decay provided that the devices can sustain a sweep of that high a reverse bias without short-circuiting.

The devices swept from an initial voltage of −1 V registered many intermittent breakdown periods in the first few days, with abrupt drops in FF and V_{OC} induced by the shunting effects. This is attributed to brief losses in the selectivity of the ZnO blocking layer, due to excessive conductivity after photo-doping [28]. Nevertheless, the decay of J_{SC}, V_{OC} and FF values correlates with the increase of the series resistance and the decrease of the shunt resistance. The same trend was observed in the devices swept from −3 V. However, the decrease in PCE of the device swept from −7 V is primarily caused by the decreasing J_{SC}, associated with a slight increase of the series resistance.

The interval between the J-V scans also has an impact on the rate of device performance degradation. For the same sweep range (−7 V to 1 V), the devices scanned every 30 minutes (or 15 times a day) show a slower degradation rate (˜24% after 100 hrs) than the devices scanned once a day, where the PCE dropped by ˜50% in the same time. The inventors also observed a significant increase in the series resistance and a drop of ˜40% in the shunt resistance of these devices. Given that the testing procedure used by the inventors provided a constant amount of light exposure setting the interval to be time dependent ensured that the scans were performed after the cells had been exposed to a roughly uniform quantity of irradiation between each J-V scan. Alternatively, for scenarios with less uniform irradiation of the cells, a method or system could be configured to perform the J-V scan in response to the cells having been exposed to a given amount of irradiation since the last scan by tracking the wattage output by the cell using means or techniques known to one skilled in the art.

The increase of the series resistance with time under light exposure in air, which was observed in all devices, can be attributed to reduced charge mobility in the BHJ layer. This is likely due to the formation of defects along the polymer chains, resulting from oxidation of the backbone thiophene rings by the various radicals photo-generated by the scission of the C—N bonds, followed by the reaction with oxygen molecules. Such oxidation can lead to an increase of trap density, which results in an increase of trapped holes in the photoactive layer. This leads to an increase in bimolecular recombination and decease in shunt resistance and consequently the fill factor. The distribution of these hole trap states extends from the HOMO level into the band gap with time during the course of aging, therefore upshifts the hole quasi-Fermi level accordingly, thereby reducing the V_{OC}. Applying a higher reverse bias voltage (and therefore a higher electrical field) helps to de-trap these charge carriers and thus enhance the flow current and maintain the V_{OC}.

The hole mobility in the PCDTBT:PC₇₀BM layer was measured under similar conditions to the devices by making bottom-gate bottom-contact OFET devices using PCDTBT:PC₇₀BM as the active layer. The initial hole mobility was measured to be 3.5×10⁻⁵ cm²/V·s, however after only 5 days of intermittent light exposure, the devices were no longer functional. This result does not correlate with the solar cell behavior shown in FIG. 1A, FIG. 1B, FIG. 1C, FIG. 1D, FIG. 1E and FIG. 1F, as those devices were still functional with PCEs higher than 3% after 5 days, which indicates that the mobility in OPV devices should still be significant.

This difference is likely due to lack of protection in the bottom-gate bottom-contact configuration of the OFET devices, in which the blend film is the top layer and is directly exposed to light and air, which is different from the inverted solar cell structure where the active layer is protected by the top electrode. To confirm this assumption, a second batch of solar cells was prepared using active layers which have been aged at different conditions: 1) active layer films were fabricated and stored in the dark for 5 days before anode deposition, and 2) active layers were fabricated and exposed to simulated sunlight under the same conditions as the OFET devices, i.e. the active layers were exposed to the intermittent solar simulated light for 5 days, before the vacuum deposition of the MoOₓ layer and Ag electrode to make the complete cell.

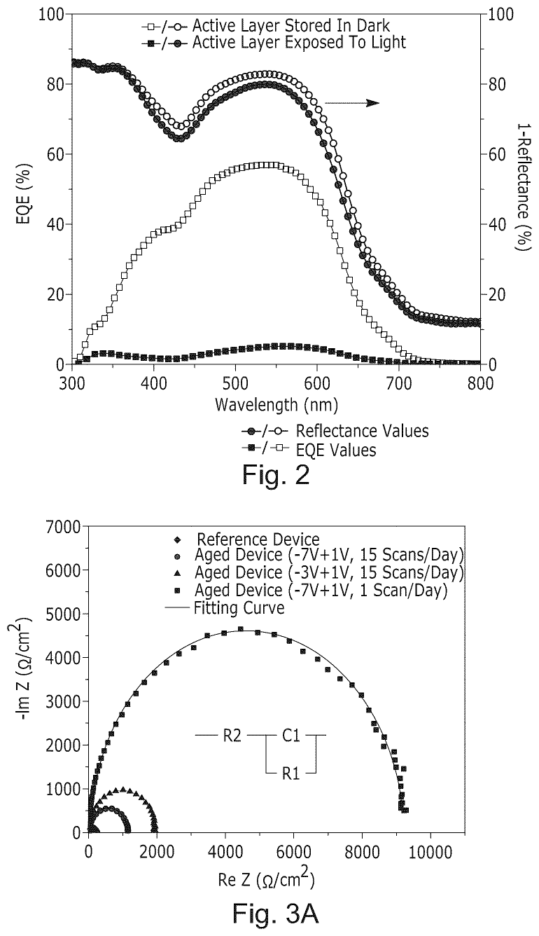

The average PCE of the devices in which the active layer was stored in dark for five days was (4.0±0.1)% (JSC=9.34±0.05 mA/cm2, VOC=0.81±0.01 V and FF=0.52±001), whereas the PCE of the device made with the active layer exposed to the intermittent solar simulated light showed an average PCE of (0.1±0.01)% (JSC=0.7±0.05 mA/cm2, VOC=0.29±0.01 V and FF=0.40±0.02). This discrepancy is correlated with the difference seen in their representative EQE spectra, shown in FIG. 2. However, the measured total absorption of the devices (equal to 1-reflectance when optical scattering is neglected) is quite comparable.

The low photocurrent in the device with the active layer exposed to light is likely associated with the accumulation of photo-oxidation induced defects in the bulk that significantly impaired the charge transport properties. On the other hand, when the completed devices were irradiated in air as presented in FIG. 1A, FIG. 1B, FIG. 1C, FIG. 1D, FIG. 1E and FIG. 1F, the MoOₓ/Ag top electrode hinders the diffusion of oxygen into the BHJ film and the photo-oxidation process is consequently mitigated, slowing down the degradation process. Therefore the device with the exposed active layer represents an extreme photo-oxidation case, where the active layer is essentially no longer functional due to the defects. This observation highlights the secondary role that the top electrode layer performs as a barrier layer.

In order to further investigate the electrical properties of the devices, the frequency dependence of the device impedance was measured using a technique commonly referred to as impedance spectroscopy.

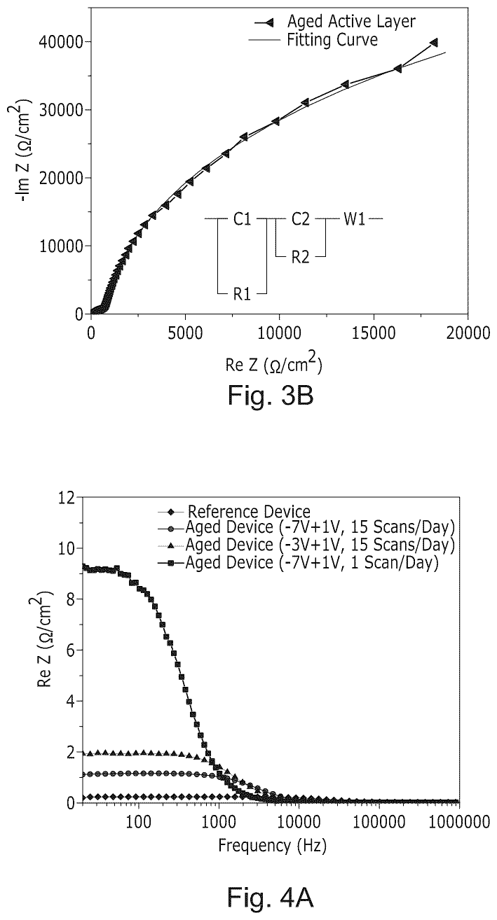

FIG. 3A presents Cole-Cole plots measured from a fresh device and aged devices presented in FIG. 1A, FIG. 1B, FIG. 1C, FIG. 1D, FIG. 1E and FIG. 1F, at frequencies ranging from 20 Hz to 1 MHz. Each Cole-Cole plot has a single semicircle in the plot of the imaginary part vs. the real part of the complex impedance (Z). Such semicircles can be reproduced with an equivalent circuit—a parallel resistance-capacitor R1C1 element with a series resistance R2, as shown in the inset of FIG. 3A. R2 represents the ohmic resistance including the electrodes and interlayers. R1 is attributed to the bulk resistance of the PCDTBT:PC₇₀BM film, and C1 is the geometrical capacitance of the device. The relative deviation of the calculated spectrum from the experimental data is within 3%.

FIG. 3B shows the impedance spectrum of a device with a photo-oxidized active layer from the second batch of devices. This spectrum clearly presents a different shape to those in FIG. 3A. The fitted curve suggests an equivalent circuit composed of two RC units in series with a Warburg element. The R1C1 pair (R1=98 kΩ, C1=80 nF) corresponds to the BHJ layer. The R2C2 (R2=658Ω, C2=177 nF) pair likely corresponds to the PCDTBT:PC₇₀BM/MoOₓ interface and can be associated with a charge accumulation that cannot be effectively extracted through the interface. This is likely due to the formation of a high density of defects on the surface of the active layer, induced by the photo-oxidation resulting from the direct irradiation of the active layer. The Warburg element (W=12.9 kΩ/s) gives a characteristic trend in the Cole-Cole plot, namely, a linear increase in Z values at low frequencies. It describes the dispersive process associated to the slow charge diffusion effect and trapping. This data indicates a large barrier at the interface between the active layer and MoOₓ/Ag electrode, which explains the high series resistance of the devices (>90Ω) and highlights the effect of photo-oxidation in the extreme case.

The values of the circuit elements (inset in FIG. 3A), for a fresh device and devices aged under AM 1.5 G irradiation with different J-V characterization conditions, are listed below in Table 1. The values of R1 and R2 increase in aged devices. In particular R1 increases by 5 to 9 times when the devices are scanned from −7 V and −3 V respectively (15 scans/day), and further increases by more than 40 times in the device which was scanned once a day. This indicates that the charge transport across the bulk layer becomes more difficult, probably due to the increased density of trapped charge carriers, which correlates with the observed evolution of PV parameters at different aging conditions. The data shows that regular application of a large reverse bias inhibits this resistance increase, probably due to the de-trapping effect of the reverse bias, which reduces the buildup of trapped charges.

TABLE 1
The fitted parameter of each element in the equivalent circuit
of a fresh PCDTBT:PC₇₀BM device and devices aged under AM 1.5
G irradiation with different J-V characterization conditions.

| Device condition | R1(Ω) | C1 (nF) | R2 (Ω) | τ (μs) |
|---|---|---|---|---|
| Fresh (unaged) | 220.1 | 32.5 | 11.6 | 7.0 |
| Aged (−7 V/15 scans) | 1124.5 | 48.8 | 15.9 | 54.8 |
| Aged (−3 V/15 scans) | 1928.1 | 50.7 | 25.2 | 97.0 |
| Aged (−7 V/1 scan) | 9154.9 | 47.6 | 56.1 | 435.6 |

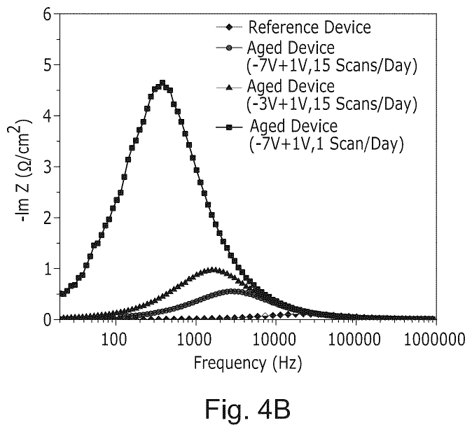

FIG. 4A shows the real part of the complex impedance (i.e. resistance) of the reference (fresh) device and aged devices characterized under different conditions. The resistance of each device decreases as the frequency increases from 20 Hz to 1 MHz, Two distinct plateaus can be observed at low (˜<100 Hz) and high (>100 kHz) frequencies. In the low frequency region, the value of the plateau increases with aging and follows the same trend as the size of the semicircles of Cole-Cole plots, as a function of aging conditions. This is attributed to PCDTBT:PC₇₀BM bulk resistance (R1). FIG. 4B shows the imaginary part of the complex impedance. The frequency (fₚ) at which Im(Z) reaches the maximum corresponds to the maximum of Cole-Cole plots, and shifts to lower frequencies for all aged devices, as compared with the reference device

The maximum of the semicircle in the Cole-Cole plots is given by 2πfₚτ=1, where τ is the dielectric relaxation time, associated with charge carrier extraction time. The τ values of different devices are presented in above in Table 1. The τ of the reference device is the smallest, which suggests relatively efficient charge transport across the active layer. The increase in the τ values of aged devices under different conditions follows the same trend as their rate of decay (FIG. 1A). The degradation rate of the electrical properties of aging devices clearly depends on the frequency and the range of the J-V scans.

### CONCLUSIONS

The inventors have developed methods and systems for applying frequent J-V sweeps with a large reverse bias component. The inventor's findings show that such approaches have a significant impact on the magnitude of the photo-induced degradation in such solar cells. Repeated application of large reverse bias slows down the device degradation processes in comparison with devices undergoing smaller range and less frequent sweeps, by de-trapping the charge carriers. In addition, the inventors have observed significant mobility degradation when un-encapsulated active layers are exposed to light, highlighting the important role that the electrodes perform in inhibiting the diffusion of oxygen into the active layer, and consequently slowing down the photo-oxidation process which causes PCE degradation. Impedance spectroscopy measurements of aged cells demonstrated that the PCDTBT:PC₇₀BM bulk layer becomes more resistive over time, and that this resistance increase is slowed by regular application of large reverse bias voltage to the devices.

While the above description provides examples of one or more apparatuses or methods, it will be appreciated that other apparatuses or methods may be within the scope of the accompanying claims as would be understood to one skilled in the art.

1. A method for reducing solar cell degradation comprising:
intermittently applying a reverse bias voltage during a current-voltage sweep to the cell.

2. The method of claim 1 wherein the solar cell is formed from: an organic semiconductor, perovskite, quantum dots, metal chalcogenides, or metal oxides.

3. The method of claim 1 or wherein the current-voltage sweep scans from less than −7V to +1V.

4. The method of claim 1 wherein the current-voltage sweep occurs at least once per day.

5. The method of claim 1 wherein the current voltage sweep is performed in at most 15 seconds.

6. The method of claim 1 wherein the current-voltage sweep occurs every time the solar cell has been irradiated with a predetermined wattage.

7. (canceled)

8. (canceled)

9. (canceled)

10. (canceled)

11. (canceled)

12. (canceled)
